(19) United States
(12) Patent Application Publication
(10) Pub. No.: US 2009/0321763 A1
(43) Pub. Date: Dec. 31, 2009

(54) LIGHT EMITTING DIODE

(75) Inventor: CHIA-SHOU CHANG, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: FOXCONN TECHNOLOGY CO., LTD., Tu-Cheng (TW)

(21) Appl. No.: 12/248,900

(22) Filed: Oct. 10, 2008

(30) Foreign Application Priority Data
Jun. 27, 2008 (CN) 200810068063.5

(51) Int. Cl. H01L 33/00

(52) U.S. Cl. 257/98; 257/E33.059; 257/E33.067

(57) ABSTRACT

An LED (20) includes a chip (21), a base (22) and an encapsulation (24). The chip is disposed on a top of the base in a concave depression (220) thereof. The encapsulation is received in the depression encapsulating the chip. The encapsulation includes a light output surface (240) facing the chip. The light output surface includes a middle convergent surface (240A) and a reflective surface (240B) around the convergent surface. The reflective surface is a part of a spherical surface and a centre (F) of the spherical surface of the reflective surface is below the chip. The convergent surface is curved and protrudes upwardly relative to the reflective surface.

### BACKGROUND

1. Field of the Invention

The disclosure generally relates to a light emitting diode (LED), and more particularly to an LED which can provide a focused beam of light.

2. Description of Related Art

Light emitting diodes (LEDs) are commonly used as light sources in applications including lighting, signaling, signage and displays. The LED has several advantages over incandescent and fluorescent lamps, including high efficiency, high brightness, long life, and stable light output. The LED creates much brighter and wider illumination with lower power consumption.

A commonly used LED generally includes a chip encased in an encapsulation. The encapsulation is transparent or translucent epoxy resin, usually with an output surface over the chip. The chip emits light rays towards the output surface. Because the encapsulation has a refractive index higher than ambient air, the light rays incident on the output surface are dispersed towards the ambient air over the output surface. However, in some applications, a light source using LED is required to generate a focused beam of light rays, such as an indicator.

Therefore, there is a need for an LED which can provide a focused beam of light rays.

### SUMMARY

An LED according to an exemplary embodiment includes a chip, a base and an encapsulation. The chip is disposed on a top of the base in a concave depression thereof. The encapsulation is received in the depression. The encapsulation includes a light output surface facing the chip. The light output surface includes a middle convergent surface and a reflective surface around the convergent surface. The reflective surface is a part of a spherical surface and a centre of the spherical surface of the reflective surface is below the chip. The convergent surface is curved and protrudes upwardly relative to the reflective surface.

Other advantages and novel features of the disclosure will become more apparent from the following detailed description of an embodiment/embodiments when taken in conjunction with the accompanying drawings.

### BRIEF DESCRIPTION OF THE DRAWINGS

FIG. 1 is a cross-section of an LED in accordance with an embodiment of the prevent invention.

FIG. 2 is a top plan view of the LED shown in FIG. 1.

### DETAILED DESCRIPTION

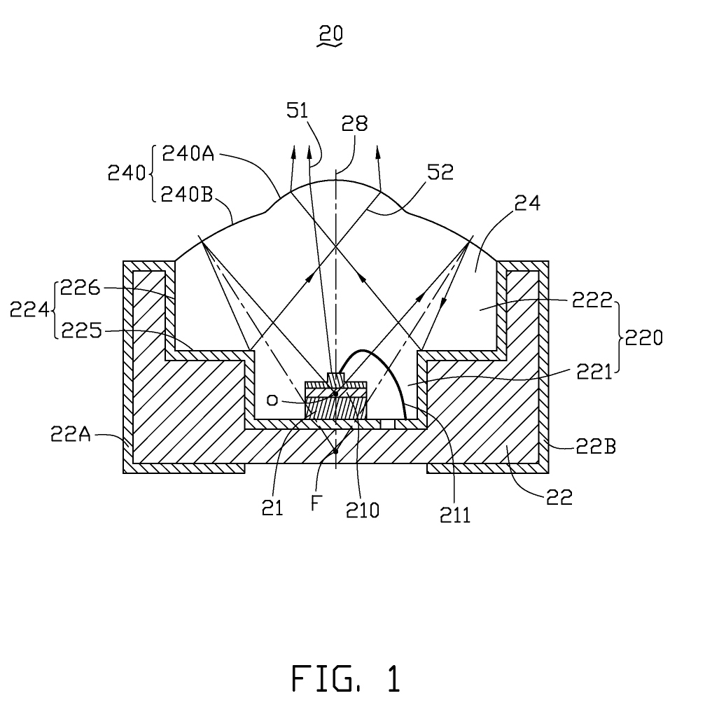

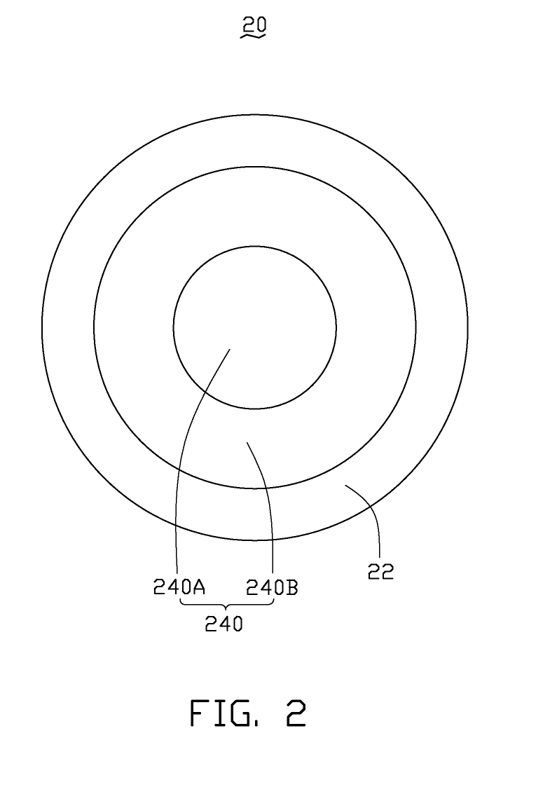

Referring to FIGS. 1 and 2, an LED 20 in accordance with an embodiment of the disclosure is illustrated. The LED 20 comprises a chip 21, a base 22 and an encapsulation 24. The chip 21 is disposed on a top of the base 22 in a concave depression 220 thereof. The encapsulation 24 is received in the depression 220 and encapsulates the chip 21. The chip 21 emits light rays. The light rays pass through the encapsulation 24 and finally leave the LED 20.

The LED 20 has a central line 28, extending therethrough from top to bottom. The chip 21 has a light emitting layer 210, generating light rays of different colors according to actual need, for example blue light rays, red light rays, or yellow light rays. The light emitting layer 210 has a central point O.

The base 22 has a cup-shaped configuration, defining a concave depression 220 in a top thereof with a step-shaped cross section. The depression 220 includes a first depression 221 and a second depression 222. The first depression 221 is located in a middle of a bottom of the base 22. The second depression 222 is located above the first depression 221 and adjacent to the top of the base 22. The second depression 222 has a bigger opening than the first depression 221. A step 224 is formed in the depression 220. The chip 21 is received in the first depression 221. Two electrodes 22A, 22B are attached in a surface of the base 22. The electrodes 22A, 22B are separated and insulated from each other. The chip 21 is mounted on the electrode 22A and connected with the electrode 22B via a golden line 211. Thus, the chip 21 is electrically connected to a printed circuit board (not shown) on which the LED 20 is mounted, in which the electrodes 22A, 22B are soldered to the printed circuit board.

The step 224 faces the second depression 222. The step 224 includes a horizontal wall 225 and a vertical wall 226. The horizontal wall 225 is between the first depression 221 and the second depression 222 and beside the chip 21.

The encapsulation 24, of a first light penetrable material, such as acryl, silicone or epoxy resin, redirects light from the chip 21 in addition to protecting the chip 21 from external physical shock. The encapsulation 24 fills the depression 220, and adheres to internal surfaces of the base 22 so that the chip 21 is completely covered by the encapsulation 24.

The encapsulation 24 has a curved, convex light output surface 240 on a top thereof relative to a top of the base 22. The light output surface 240 includes a middle convergent surface 240A and a reflective surface 240B around the convergent surface 240A. The convergent surface 240A is located in a central area of the light output surface 240 and protrudes upwardly relative to the reflective surface 240B. The central line 28 extends through a center of the convergent surface 240A. The convergent surface 240A is located over the chip 21. The reflective surface 240B is located over the horizontal wall 225. The reflective surface 240B is a part of a spherical surface. A centre F of the spherical surface of the reflective surface 240B is located below the central point O of the light emitting layer 210 of the chip 21. The centre F is located in the central line 28. Highly reflective material is applied on the reflective surface 240B and the walls 225, 226. The convergent surface 240A is light penetrable.

In operation, light rays are emitted from the light emitting layer 210 of the chip 21, through the encapsulation 24, and incident on the light output surface 240. A portion of the light rays 51 are directly incident on the convergent surface 240A, and then refracted convergently to an area over the light output surface 240 via the convergent surface 240A. Another portion of the light rays 52 are incident on the reflective surface 240B, because the reflective surface 240B has highly reflective material applied thereon and the center F is below the light emitting layer 210 of the chip 21, such that the another portion of the light rays 52 are accordingly reflected to the step 224, especially to the horizontal wall 225. Then, the another portion of the light rays 52 are reflected from the horizontal wall 225 to the convergent surface 240A, and at last are refracted convergently to the area over the light output surface 240. Thus, most of the light rays of the chip 21 are directly or indirectly conducted to the convergent surface 240A and then refracted to the area over the LED 20, so that the LED 20 can generate a focused beam of light rays towards the area over the LED 20. Light loss caused by total reflection is greatly reduced.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An LED comprising:
a chip comprising a light emitting layer;
a base for mounting the chip; and
an encapsulation covering the chip, the encapsulation comprising a light output surface facing the chip, the light output surface comprising a middle convergent surface and a reflective surface therearound, wherein the reflective surface comprises part of a spherical surface, a centre of the spherical surface of the reflective surface is below the light emitting layer of the chip, and the convergent surface is curved and protrudes upwardly relative to the reflective surface.

2. The LED as claimed in claim 1, wherein a central point O of the light emitting layer of the chip, the center of the spherical surface of the reflective surface and a center of the convergent surface are located along a single line.

3. The LED as claimed in claim 1, wherein the base comprises a concave depression defined therein, located in a top of the base, with the chip received in the depression, and the encapsulation fills the depression and adheres to internal surfaces of the base.

4. The LED as claimed in claim 3, wherein the light output surface is curved and convex, located in a top of the encapsulation.

5. The LED as claimed in claim 3, wherein the depression comprises a first depression and a second depression, with the first depression in a middle of a bottom of the base and the second depression above the first depression and adjacent to the top of the base, and the second depression has a larger opening than the first depression.

6. The LED as claimed in claim 5, wherein two electrodes are attached in a surface of the base, separated and insulated from each other, and the chip is mounted on one of the electrodes and connected with the other electrode via a golden line.

7. The LED as claimed in claim 5, wherein the base includes a step facing the second depression, comprising a horizontal wall above and beside the chip.

8. The LED as claimed in claim 7, wherein highly reflective material is applied on the horizontal wall of the step.

9. The LED as claimed in claim 1, wherein highly reflective material is applied on the reflective surface of the light output surface of the encapsulation.

10. An LED comprising:
a chip;
a base comprising a first depression and a second depression defined in a top thereof, the second depression comprising a bigger opening than the first depression, a step being formed in the second depression of the base and comprising a horizontal wall, the chip being received in the first depression which is located below the second depression and communicates therewith; and
an encapsulation filling the first and second depressions and encapsulating the chip in the base, the encapsulation comprising a light output surface comprising a middle convergent surface and a reflective surface around the convergent surface, wherein
at least a portion of light emitted by the chip is directed to the reflective surface, reflected to the horizontal wall of the step, reflected to the convergent surface, and refracted to an exterior of the LED.

11. The LED as claimed in claim 10, wherein the reflective surface is a part of a spherical surface, the convergent surface being curved and protruding upwardly relative to the reflective surface.

12. The LED as claimed in claim 11, wherein a center of the spherical surface of the reflective surface is below the chip.

13. The LED as claimed in claim 10, wherein highly reflective material is applied on the reflective surface of the light output surface of the encapsulation and the horizontal wall of the step.

14. An LED comprising:
a chip comprising a light emitting layer;
a base having a depressed top surface on which the chip is mounted, the top surface being light reflective; and
an encapsulation filling the depressed top surface of the base and covering the chip, the encapsulation comprising a light output surface facing the chip, the light output surface comprising a middle convergent surface and a reflective surface therearound, wherein the reflective surface comprises part of a spherical surface, a centre of the spherical surface of the reflective surface is below the light emitting layer of the chip, and the convergent surface is curved and protrudes upwardly relative to the reflective surface;
wherein at least a portion of light generated by the chip and emitted from the light emitting layer is first transmitted to the reflective surface, then reflected by the reflective surface to the depressed top surface, and finally reflected by the depressed top surface to an outside of the LED over the middle convergent surface via the middle convergent surface.

15. The LED as claimed in claim 14, wherein the depressed top surface has a step configuration, defining a large upper depression and a small lower depression.

16. The LED as claimed in claim 15, wherein the chip is received in the small lower depression.
